(19) United States
(12) Patent Application Publication
(10) Pub. No.: US 2026/0136999 A1
(43) Pub. Date: May 14, 2026

(54) SEMICONDUCTOR PACKAGE

(71) Applicant: Samsung Electronics Co., Ltd., Suwon-si (KR)

(72) Inventor: Wonbin Shin, Suwon-si (KR)

(21) Appl. No.: 19/349,696

(22) Filed: Oct. 3, 2025

(30) Foreign Application Priority Data
Nov. 12, 2024 (KR) 10-2024-0159921

(51) Int. Cl. H01L 25/18; H01L 23/00; H01L 23/48; H01L 23/498; H01L 23/538; H10D 1/68

(52) U.S. Cl. CPC H10W 90/00; H10D 1/714; H10D 1/716; H10W 20/20; H10W 70/611; H10W 70/65; H10W 70/685; H10W 90/724

(57) ABSTRACT

A semiconductor package includes a coreless circuit substrate including an insulating member having a plurality of insulating layers and a plurality of cavities, and a plurality of wiring layers respectively disposed on the plurality of insulating layers, a semiconductor chip disposed on an upper surface of the coreless circuit substrate and electrically connected to an uppermost wiring layer among the plurality of wiring layers, and a plurality of semiconductor-based chip capacitors disposed in the plurality of cavities, respectively, and each having an upper surface on which first pads are disposed and a lower surface on which second pads are disposed. The first pads are connected to a first wiring layer, adjacent to the first pads, among the plurality of wiring layers by conductive bumps, and the second pads are connected to an interconnection via of a second wiring layer, adjacent to the second pads, among the plurality of wiring layers.

### CROSS-REFERENCE TO RELATED APPLICATION(S)

This application claims the benefit under 35 U.S.C. § 119 of Korean Patent Application No. 10-2024-0159921, filed on Nov. 12, 2024, in the Korean Intellectual Property Office, the entire disclosure of which is incorporated herein by reference for all purposes.

### BACKGROUND

The present inventive concept relates to a semiconductor package.

As electronic devices become lighter and more powerful, the development of miniaturized and high-performance semiconductor packages is also required in the semiconductor packaging field. To implement miniaturization and high-performance of semiconductor packages, packaging technology that embeds passive components in circuit boards is continuously being developed.

### SUMMARY

Example embodiments provide a semiconductor package having a circuit board with passive components embedded therein.

According to example embodiments, a semiconductor package includes a coreless circuit substrate including an insulating member having a plurality of insulating layers and a plurality of cavities, and a plurality of wiring layers respectively disposed on the plurality of insulating layers and having interconnection vias connected to adjacent wiring layers; at least one semiconductor chip disposed on an upper surface of the coreless circuit substrate and electrically connected to an uppermost wiring layer among the plurality of wiring layers; and, a plurality of semiconductor-based chip capacitors disposed in the plurality of cavities, respectively, and each having an upper surface on which first pads are disposed and a lower surface on which second pads are disposed. The first pads are connected to a first wiring layer, adjacent to the first pads, among the plurality of wiring layers by conductive bumps, and the second pads are connected to an interconnection via of a second wiring layer, adjacent to the second pads, among the plurality of wiring layers.

According to example embodiments, a semiconductor package includes a coreless circuit substrate including an insulating member having a plurality of insulating layers, and a plurality of wiring layers respectively disposed on the plurality of insulating layers, an uppermost wiring layer among the plurality of wiring layers including planar patterns for pads, and each of the plurality of wiring layers excepting the uppermost wiring layer having an interconnection via connected to another adjacent wiring layer; a semiconductor chip disposed on an upper surface of the coreless circuit substrate and electrically connected to the planar patterns for pads of the uppermost wiring layer; and a plurality of semiconductor-based chip capacitors embedded in the coreless circuit substrate and having an upper surface on which first pads are arranged and a lower surface on which second pads are arranged. The first pads are connected to lower surfaces of the planar patterns for pads of the uppermost wiring layer, and the second pads are connected to an interconnection via of a wiring layer adjacent thereto among the plurality of wiring layers.

According to example embodiments, a semiconductor package includes a coreless circuit substrate including an insulating member having a plurality of insulating layers, and a plurality of wiring layers respectively disposed on the plurality of insulating layers, an uppermost wiring layer of the plurality of wiring layers including planar patterns for pads, and each of the plurality of wiring layers excepting the uppermost wiring layer having an interconnection via connected to another adjacent wiring layer; a plurality of semiconductor chips disposed on an upper surface of the coreless circuit substrate and electrically connected to the planar patterns for pads of the uppermost wiring layer; a semiconductor bridge embedded in the coreless circuit substrate and having an interconnection wiring layer electrically connecting the plurality of semiconductor chips; and a plurality of semiconductor-based chip capacitors embedded in the coreless circuit substrate and having an upper surface on which first pads are arranged and a lower surface on which second pads are arranged. The first pads are connected to a first wiring layer adjacent to the first pads among the plurality of wiring layers by first conductive bumps, and the second pads are connected to an interconnection via of a second wiring layer adjacent to the second pads among the plurality of wiring layers.

According to example embodiments, a semiconductor-based chip capacitor includes a semiconductor body having a first surface and a second surface positioned opposite to each other; a capacitor structure disposed on the first surface of the semiconductor body, and having a first electrode and a second electrode and a dielectric layer therebetween; a redistribution structure disposed on the capacitor structure, and having a redistribution layer connected to the first electrode and the second electrode; a through-electrode penetrating the semiconductor body and connected to the second electrode; first pads disposed on the redistribution structure and connected to the first electrode through the redistribution layer; and second pads disposed on the second surface of the semiconductor body and connected to the second electrode via the through-electrode.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a side cross-sectional view schematically illustrating a semiconductor package according to an example embodiment;

FIG. 2 is a plan view schematically illustrating the semiconductor package of FIG. 1;

FIG. 3 is a cross-sectional view schematically illustrating an area “A” of the semiconductor package of FIG. 1;

FIG. 4A is a side cross-sectional view schematically illustrating an example of a semiconductor-based chip capacitor embedded in a coreless circuit substrate of FIG. 1, and FIG. 4B is a partially enlarged view schematically illustrating area “B” of the semiconductor-based chip capacitor of FIG. 4A;

FIG. 5 is a side cross-sectional view schematically illustrating a semiconductor package according to an example embodiment;

FIG. 6 is a plan view schematically illustrating the semiconductor package of FIG. 5;

FIG. 7 is a side cross-sectional view schematically illustrating a semiconductor package according to an example embodiment;

FIG. 8 is a plan view schematically illustrating the semiconductor package of FIG. 7;

FIG. 9 is a side cross-sectional view schematically illustrating a semiconductor bridge embedded in a coreless circuit substrate of FIG. 7;

FIG. 10 is a cross-sectional view illustrating an example of a semiconductor bridge that may be employed in a semiconductor package according to an example embodiment;

FIGS. 11A to 11H are cross-sectional views illustrating main processes in a method of manufacturing a semiconductor package according to an example embodiment; and

FIGS. 12A to 12C are cross-sectional views illustrating main processes of a method of manufacturing a semiconductor package according to an example embodiment.

### DETAILED DESCRIPTION

Hereinafter, example embodiments will be described with reference to the accompanying drawings. Like reference characters refer to like elements throughout.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to emphasize this meaning, unless the context or other statements indicate otherwise.

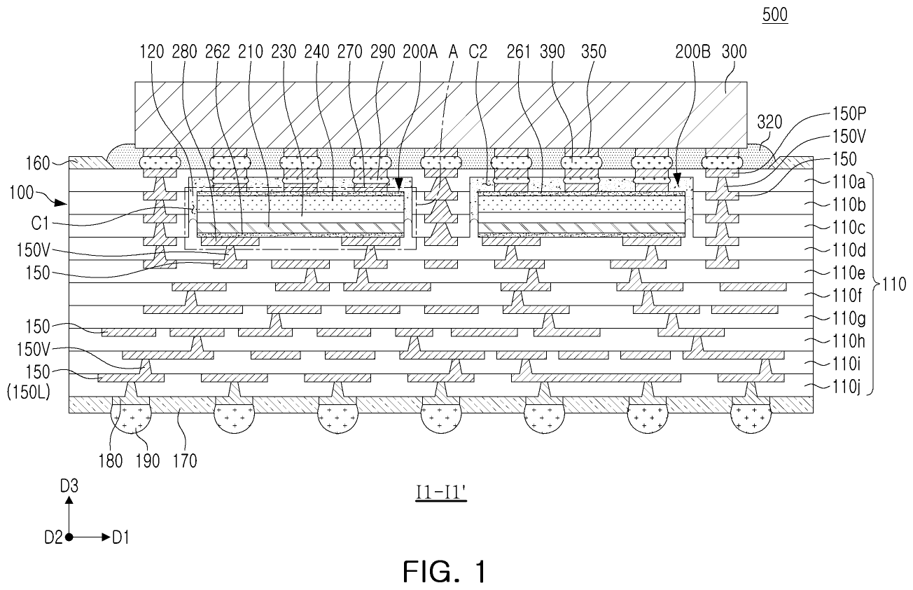

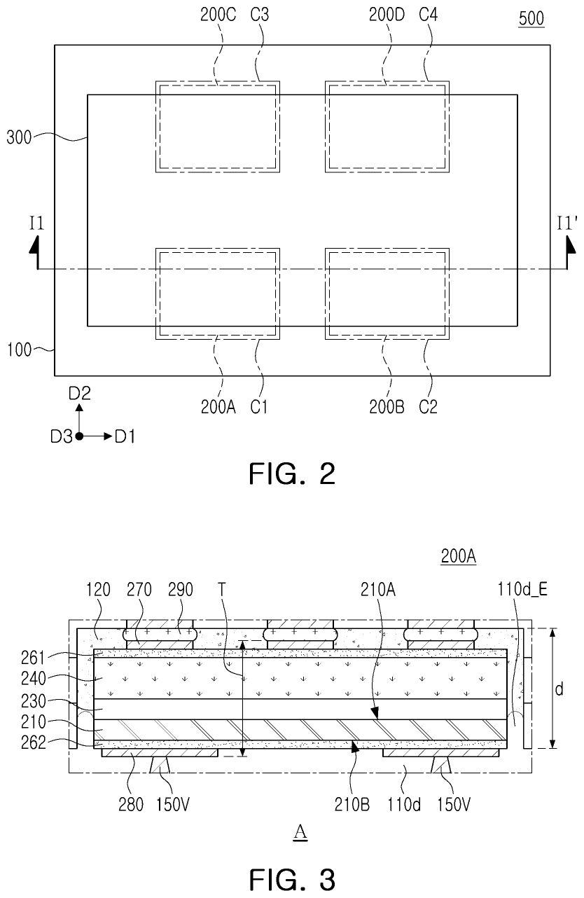

FIG. 1 is a cross-sectional side view schematically illustrating a semiconductor package according to an example embodiment, and FIG. 2 is a plan view illustrating the semiconductor package of FIG. 1. In this case, FIG. 1 may be understood as a cross-sectional side view taken along line I1-I1′ of the semiconductor package of FIG. 2.

Referring to FIGS. 1 and 2, a semiconductor package 500 according to an example embodiment may include a coreless circuit substrate 100 having a plurality of semiconductor-based chip capacitors 200A, 200B, 200C and 200D embedded therein, and a semiconductor chip 300 mounted on the coreless circuit substrate 100.

The coreless circuit substrate 100 employed in the present embodiment may include an insulating member 110 having a plurality of insulating layers 110a to 110j, and a plurality of wiring layers 150 respectively disposed on the plurality of insulating layers 110a to 110j. The plurality of wiring layers 150 may include interconnection vias 150V that connect to adjacent wiring layers 150.

The coreless circuit substrate 100 may be an embedded trace substrate (ETS) formed by a build-up process. The interconnection vias 150V of the plurality of wiring layers 150 may have a width that narrows toward the upper surface of the coreless circuit substrate 100 in a single build-up direction. For example, the interconnection vias 150V may be tapered in a direction toward the upper surface of the coreless circuit substrate 100. In addition, the coreless circuit substrate 100 does not include a core layer containing a reinforcing material such as a non-woven glass fabric or an aramid fiber to reduce the overall thickness of the semiconductor package 500.

Each of the plurality of insulating layers 110a to 110j may be formed of or include an insulating resin. The insulating resin may include a thermosetting resin such as an epoxy resin or a thermoplastic resin such as a polyimide. For example, each of the plurality of insulating layers 110a to 110j may include a photosensitive resin such as prepreg, ABF, Flame Retardant 4 (FR-4), Bismaleimide Triazine (BT), or Photo-Imageable Dielectric (PID).

The plurality of wiring layers 150 may be formed of or include a metal material including, for example, copper (Cu), aluminum (Al), silver (Ag), tin (Sn), gold (Au), nickel (Ni), lead (Pb), titanium (Ti), or alloys thereof. The interconnection via 150V may similarly include a metal material including copper (Cu), aluminum (Al), silver (Ag), tin (Sn), gold (Au), nickel (Ni), lead (Pb), titanium (Ti), or alloys thereof. The interconnection via 150V is illustrated as a filled via in which a metal material is filled inside a via hole of each insulating layer, but in some embodiments, may have a conformal via shape in which a metal material is formed along an inner wall of the via hole. In some embodiments, the interconnection via 150V may have an integrated structure formed by a plating process together with the wiring layer 150.

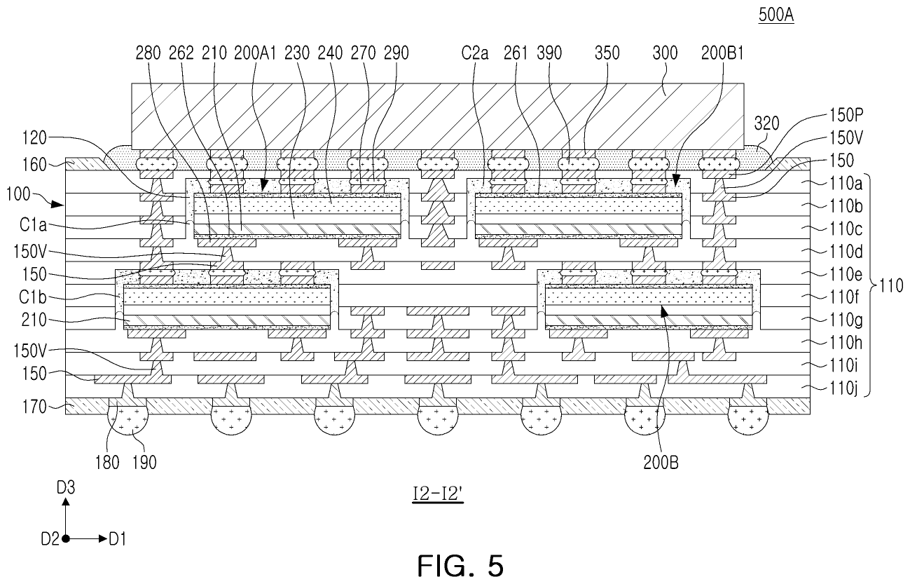

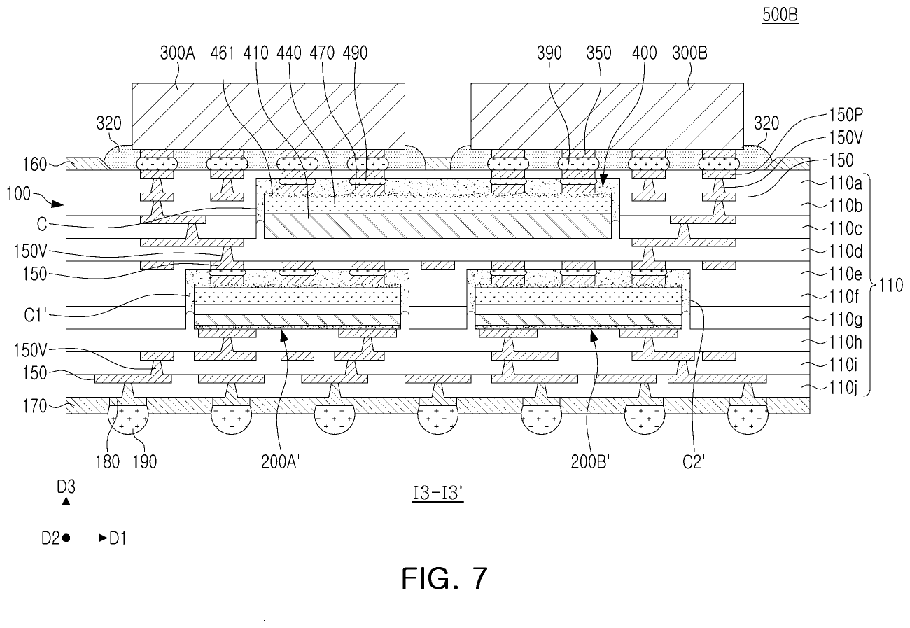

The coreless circuit substrate 100 may include a plurality of cavities C1, C2, C3 and C4 formed in the insulating member 110. In the present embodiment, four cavities C1, C2, C3 and C4 may be disposed in the horizontal directions D1 and D2 at the same level of the coreless circuit substrate 100. The four cavities C1, C2, C3 and C4 may be provided with a depth corresponding to a portion of the uppermost insulating layer 110a and two next-highest insulating layers 110b and 110c. The present inventive concept is not limited thereto, and the cavities C1, C2, C3 and C4 may have a depth corresponding to one to four insulating layers depending on the size of the chip capacitors 200A, 200B, 200C and 200D. Also, although four cavities C1, C2, C3 and C4 are exemplified as having the same depth at the same level, in some embodiments, some cavities may have different depths or be located at different levels (see FIGS. 5 and 7).

In this embodiment, each of the plurality of cavities C1, C2, C3 and C4 may have an opening facing the lower surface of the coreless circuit substrate 100. A plurality of semiconductor-based chip capacitors 200A, 200B, 200C and 200D may be disposed in the plurality of cavities C1, C2, C3 and C4, respectively.

FIG. 3 is a cross-sectional view illustrating an enlarged “A” area of the semiconductor package of FIG. 1.

Referring to FIG. 3 in combination with FIGS. 1 and 2, the surroundings of the chip capacitors 200A, 200B, 200C and 200D in the cavities C1, C2, C3 and C4 may include a filling material. After the chip capacitors 200A, 200B, 200C and 200D are mounted, the filling material may be applied to the remaining space of the cavities C1, C2, C3 and C4. For example, the filling material may include Ajinomoto Build-up Film (ABF).

In the present embodiment, the insulating layer 110d covering the cavities C1, C2, C3 and C4 among the plurality of insulating layers 110a to 110j may fill a part of the remaining space of the cavities C1, C2, C3 and C4 in which the chip capacitors 200A, 200B, 200C and 200D are disposed through the opening. For example, the insulating layer 110d may have a portion (110d_E) that fills a portion of the space along the side of the chip capacitor 200A. Each of the cavities C2 to C4 may also have a portion 110d_E that fills a portion of the space along the sides of the respective chip capacitors 200B to 200D. In addition, the remainder of each of the cavities C1, C2, C3 and C4 may be filled with a filling material 120. The filling material 120 may include an ABF material.

In the present embodiment, four cavities C1, C2, C3 and C4 may be disposed in the upper region of the coreless circuit substrate 100. The chip capacitors 200A, 200B, 200C and 200D may be mounted in the four cavities C1, C2, C3 and C4 and disposed adjacent to the semiconductor chip 300, respectively. This arrangement may improve power integrity characteristics.

The chip capacitors 200A, 200B, 200C and 200D employed in the present embodiment may have a double-sided pad structure. For example, first pads 270 and second pads 280 may be disposed on the upper and lower surfaces of the chip capacitors 200A, 200B, 200C and 200D, respectively. The first pads 270 may be connected to the uppermost wiring layer 150 within the insulating layer 110a that provides the lower surface of the cavities C1, C2, C3 and C4, and the second pads 280 may be connected to the wiring layer 150 on the insulating layer 110d that covers the cavities C1, C2, C3, and C4.

As illustrated in FIG. 1 and FIG. 3, the uppermost wiring layer 150 within the insulating layer 110a may be disposed between the semiconductor-based chip capacitor 200A and the semiconductor chip 300. The uppermost wiring layer 150 may include planar patterns for pads 150P. The planar patterns for pads 150P may be arranged to correspond to chip pads 350 of a semiconductor chip 300, respectively. The chip pads 350 of the semiconductor chip 300 may be connected to upper surfaces of the planar patterns for pads 150P by second conductive bumps 390. The first pads 270 of the chip capacitors 200A, 200B, 200C and 200D may be connected to lower surfaces of the planar patterns for pads 150P located within cavities C1, C2, C3 and C4 of the planar patterns for pads 150P by the first conductive bumps 290. For example, the first conductive bumps 290 may contact upper surfaces of the first pads 270 and lower surfaces of the planar patterns for pads 150P. In this way, since the electrical paths between the semiconductor-based chip capacitors 200A, 200B, 200C and 200D and the semiconductor chip 300 are greatly shortened, excellent power integrity (PI) characteristics may be secured.

In addition, unlike the connection method of the first pads 270, the second pads 280 may be directly connected to the wiring layer 150 on the insulating layer 110d covering the cavities C1, C2, C3 and C4 and the interconnection vias 150V penetrating the insulating layer 110d. For example, the second pads 280 may contact the interconnection vias 150V penetrating the insulating layer 110d. In this way, the semiconductor-based chip capacitors 200A, 200B, 200C and 200D may improve the degree of freedom of connection with the wiring layer 150 of the coreless circuit substrate 100.

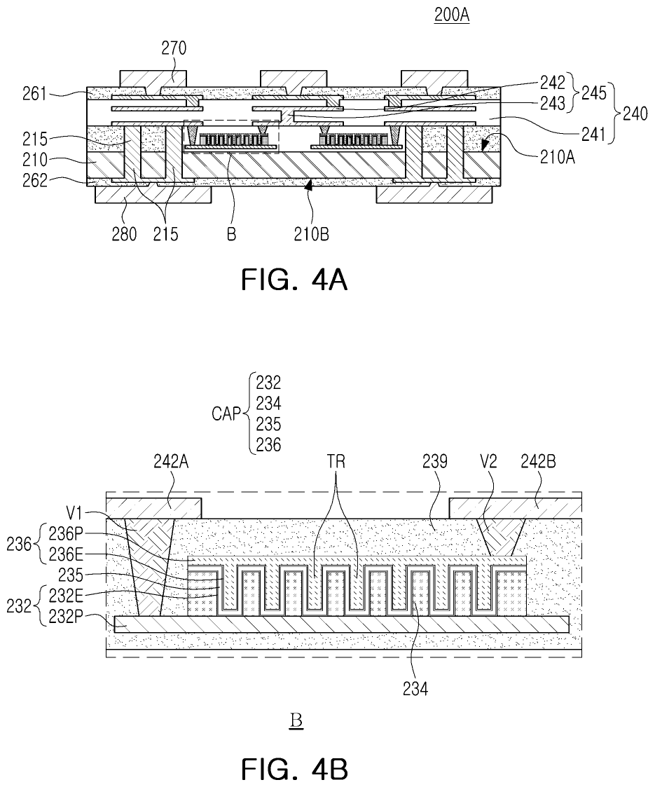

Hereinafter, examples of detailed configurations of semiconductor-based chip capacitors employed in the present embodiment will be described with reference to FIGS. 4A and 4B.

FIG. 4A is a cross-sectional view illustrating an example of a semiconductor-based chip capacitor embedded in the coreless circuit substrate of FIG. 1, and FIG. 4B is an enlarged view illustrating a portion of “B” of the semiconductor-based chip capacitor of FIG. 4A.

Referring to FIGS. 4A and 4B together with FIG. 3, each of the semiconductor-based chip capacitors 200A, 200B, 200C and 200D employed in the present embodiment may include a semiconductor body 210 having a first surface 210A and a second surface 210B positioned opposite to each other, a capacitor structure 230 on the first surface 210A of the semiconductor body 210, and a redistribution structure 240 on the capacitor structure 230. In the semiconductor package 500, chip capacitors 200A, 200B, 200C and 200D may be disposed so that the first surface 210A of the semiconductor body 210 faces the upper surface (or semiconductor chip 300) of the coreless circuit substrate 100. For example, the semiconductor body 210 may be a silicon substrate.

In the present embodiment, the coreless circuit substrate 100 may reinforce the rigidity of the coreless circuit substrate 100 by embedding semiconductor-based chip capacitors 200A, 200B, 200C and 200D having relatively high rigidity instead of the core layer. As described above, the semiconductor-based chip capacitors 200A, 200B, 200C and 200D may be aligned so as not to overlap and to be widely distributed in the horizontal directions D1 and D2 on the same level of the coreless circuit substrate 100, thereby more effectively reinforcing the rigidity of the coreless circuit substrate 100.

In addition, the capacitor structure 230 may include a first electrode 232 and a second electrode 236 and a dielectric layer 235 therebetween. The capacitor structure 230 employed in the present embodiment may include a trench-structured capacitor CAP disposed within an interlayer insulating layer239. The interlayer insulating layer 231 may completely surround the trench-structured capacitor CAP. In this way, the chip capacitors 200A, 200B, 200C and 200D employed in the present embodiment have a relatively small thickness, unlike conventional ceramic laminated capacitors, so that the rigidity may be reinforced without significantly increasing the thickness of the coreless circuit substrate 100. For example, the thickness T of the semiconductor-based chip capacitors 200A, 200B, 200C and 200D may be in the range of 20 μm to 70 μm. The thickness T of the semiconductor-based chip capacitors 200A, 200B, 200C and 200D may be a thickness measured from a bottom surface of second pads 280 to an upper surface of the first pads 270.

Referring to FIGS. 4A and 4B, the trench-structured capacitor CAP is disposed on the first surface 210A of the semiconductor body 210 and may include a base insulating layer 234 having a plurality of trenches TR. The first and second electrodes 232 and 236 include first and second internal electrodes 232E and 236E that are conformally formed along a surface within a trench TR of a base insulating layer 234, respectively, and a dielectric layer 235 may be disposed between the first and second internal electrodes 232E and 236E. The first electrode 232 includes a first pad electrode 232P that is disposed on a lower surface of the base insulating layer 234, and the first pad electrode 232P may be connected to the first internal electrode 232E through the bottom of the trench TR. The second electrode 236 includes a second pad electrode 236P connected to the second inner electrode 236E on the base insulating layer 234, and the second pad electrode 236P may be configured to fill the inside of the trench TR. An insulating layer 239 may surround the capacitor CAP. In example embodiments, the insulating layer 239 may contact the capacitor CAP.

The redistribution structure 240 may include a redistribution insulating layer 241 and a redistribution layer 245 within the redistribution insulating layer 241. The redistribution layer 245 includes a redistribution pattern 242 and a redistribution via 243, and may be configured to provide a first path connected to the first pads 270 and a second path connected to the second pads 280. In this embodiment, the second path of the redistribution layer 245 may be connected by the redistribution pattern 242A to the first pad electrode 232P through the first via V1, and the first path of the redistribution layer 245 may be connected by the redistribution pattern 242B to the second pad electrode 236P through the second via V2.

A first passivation film 261 opening contact area of a redistribution pattern is disposed on a redistribution structure 240, and first pads 270 are disposed on the first passivation film 261 and may be connected to a first path of a redistribution layer 245 through the contact areas of the redistribution pattern. Meanwhile, a semiconductor-based chip capacitor 200A includes a through-electrode 215 penetrating a semiconductor body 210, and the through-electrode 215 may be connected to a second path of the redistribution layer 245. On the second surface of the semiconductor body 210, a second passivation film 262 is disposed to open a portion of the through-electrode 215, and second pads 280 are disposed on the second passivation film 262 and may be connected to the second path of the redistribution layer 245 through the through-electrode 215.

In this way, the semiconductor-based chip capacitor 200A employed in the present embodiment may have a double-sided pad structure having first pads 270 and second pads 280.

In the present embodiment, the first pads 270 are connected to the second electrode 236 of the capacitor CAP through the first path of the redistribution layer 245, and the second pads 280 are connected to the first electrode 232 of the capacitor CAP through the through-electrode 215 and the second path of the redistribution layer 245, but are not limited thereto, and in some embodiments, the path of the redistribution layer 245 may be reconfigured so that at least some of the first pads 270 disposed on the upper surface are connected to the first electrode 232 of the capacitor CAP, and at least some of the second pads 280 disposed on the lower surface may be connected to the second electrode 236 of the capacitor CAP.

A first passivation layer 160 is disposed on the upper surface of the coreless circuit substrate 100, and the first passivation layer 160 may be formed to open an area where a semiconductor chip 300 is mounted. An underfill resin 320 may be disposed in a space between the coreless circuit substrate 100 and the semiconductor chip 300. For example, the underfill resin 320 may be formed to surround second conductive bumps 390 connecting the chip pads 350 and the planar pattern for pad 150P. The underfill resin 320 may include a polymer material such as an epoxy resin.

A second passivation layer 170 is disposed on the lower surface of the coreless circuit substrate 100, and the second passivation layer 170 may have a plurality of openings that open contact areas of the lowermost redistribution layer 150L. A Under Bump Metal (UBM) layer 180 connected to the contact area may be formed through a plurality of openings. External connection conductors 190 may respectively be formed on the UBM layer 180.

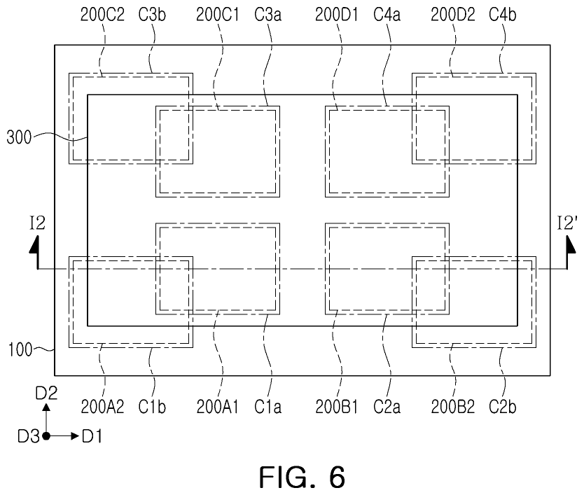

FIG. 5 is a side cross-sectional view schematically illustrating a semiconductor package according to an example embodiment, and FIG. 6 is a plan view illustrating the semiconductor package of FIG. 5. In this case, FIG. 5 may be understood as a side cross-sectional view taken by cutting the semiconductor package of FIG. 6 along line I2-I2′.

Referring to FIGS. 5 and 6, the semiconductor package 500A according to the present embodiment may be understood to have a similar structure to the semiconductor package 500 illustrated in FIGS. 1 to 3, except that a plurality of semiconductor-based chip capacitors 200A1, 200B1, 200C1, 200D1, 200A2, 200B2, 200C2, and 200D2 are disposed on different levels of the coreless circuit substrate 100, respectively. In addition, the components of the present embodiment may be understood by referring to the description of the same or similar components of the semiconductor package 500 illustrated in FIGS. 1 to 3, unless there is a specifically contrary description.

In the present embodiment, the plurality of cavities may be divided into a first group of cavities C1a, C2a, C3a and C4a located at first levels of the coreless circuit substrate 100, and a second group of cavities C1b, C2b, C3b and C4b located at a second level lower than the first level of the coreless circuit substrate 100. The first level may be located in an upper region adjacent to the semiconductor chip 300, similar to the previous embodiment.

Chip capacitors 200A1, 200B1, 200C1 and 200D1 of the first group may be mounted in the cavities C1a, C2a, C3a and C4a of the first group, respectively, and chip capacitors 200A2, 200B2, 200C2 and 200D2 of the second group may be mounted in the cavities C1b, C2b, C3b and C4b of the second group, respectively. Each of the chip capacitors 200A1, 200B1, 200C1 and 200D1 of the first group and the chip capacitors 200A2, 200B2, 200C2 and 200D2 of the second group may be substantially the same as the chip capacitors 200A, 200B, 200C and 200D.

First, the chip capacitors 200A1, 200B1, 200C1 and 200D1 of the first group may be connected to the lower surfaces of the planar patterns for pads 150P, which are the uppermost wiring layers respectively exposed by the cavities, by the first conductive bumps 290. The chip pads 350 of the semiconductor chip 300 may be connected to the upper surfaces of the planar patterns for pads 150P by the second conductive bumps 390.

In this way, the electrical path between the chip capacitors 200A1, 200B1, 200C1 and 200D1 of the first group and the semiconductor chip 300 is greatly shortened, so that excellent power integrity (PI) characteristics may be secured.

The second pads 280 may be directly connected to the interconnection vias 150V penetrating the insulating layer 110d on the wiring layer 150 covering the cavities C1a, C2a, C3a and C4a. In this way, the chip capacitors 200A1, 200B1, 200C1 and 200D1 of the first group may improve the degree of freedom of connection with the wiring layer 150 of the coreless circuit substrate 100.

In the present embodiment, the chip capacitors 200A2, 200B2, 200C2 and 200D2 of the second group may be mounted on a second level lower than the first level of the chip capacitors 200A1, 200B1, 200C1 and 200D1 of the first group. The chip capacitors 200A2, 200B2, 200C2 and 200D2 of the second group may be connected to the wiring layer 150 in a similar manner to the chip capacitors 200A1, 200B1, 200C1 and 200D 1 of the first group. The first pads 270 of the chip capacitors 200A2, 200B2, 200C2 and 200D2 of the second group are connected to the wiring layer 150 exposed on the bottom of the cavities C1b, C2b, C3b and C4b of the second group by the first conductive bumps 290, and the second pads 280 of the chip capacitors 200A2, 200B2, 200C2 and 200D2 of the second group are partially covered by the insulating layer 100h covering the cavities C1b, C2b, C3b and C4b of the second group, and the wiring layer on the insulating layer 100h may be connected to the second pads 280 of the chip capacitors 200A2, 200B2, 200C2 and 200D2 of the second group by the interconnection via 150V penetrating the insulating layer 100h.

In this embodiment, the rigidity of the coreless circuit substrate 100 may be reinforced by embedding the first group of chip capacitors 200A1, 200B1, 200C1 and 200D1 and the second group of chip capacitors 200A2, 200B2, 200C2 and 200D2 at different levels within the coreless circuit substrate 100. The first group of chip capacitors 200A1, 200B1, 200C1 and 200D1 and the second group of chip capacitors 200A2, 200B2, 200C2 and 200D2 may be aligned so as not to overlap in the horizontal directions D1 and D2 at respective levels, and may be arranged so as not to completely overlap each other in the thickness direction D3 of the coreless circuit substrate 100 to enhance the rigidity reinforcement effect.

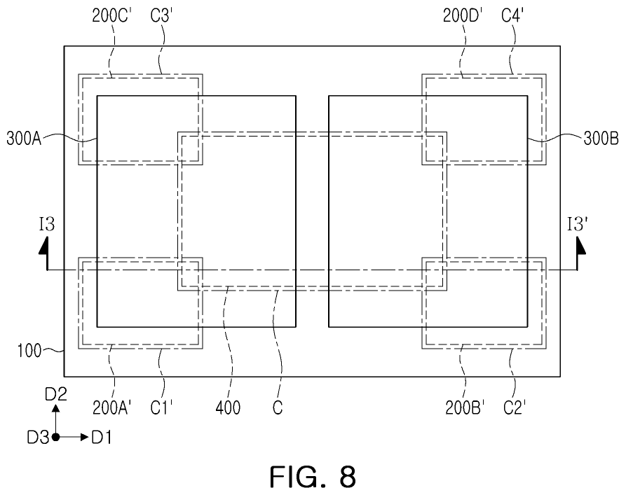

FIG. 7 is a side cross-sectional view schematically illustrating a semiconductor package according to an example embodiment, and FIG. 8 is a plan view illustrating the semiconductor package of FIG. 7. In this case, FIG. 7 may be understood as a side cross-sectional view taken along line I3-I3′ of the semiconductor package of FIG. 8.

Referring to FIG. 7 and FIG. 8, the semiconductor package 500B according to the present embodiment may be understood as having a structure similar to the semiconductor package 500 illustrated in FIG. 1 to FIG. 3, except that a semiconductor bridge 400 is disposed on the upper level of the coreless circuit substrate 100 and a plurality of semiconductor-based chip capacitors 200A′, 200B′, 200C′ and 200D′ are disposed on the lower level. In addition, the components of the present embodiment may be understood by referring to the description of the same or similar components of the semiconductor package 500 illustrated in FIG. 1 to FIG. 3, unless otherwise specifically described.

A semiconductor package 500B according to the present embodiment may include first and second semiconductor chips 300A and 300B. The first and second semiconductor chips 300A and 300B may be interconnected by a semiconductor bridge 400 embedded adjacent to an upper surface of a coreless circuit substrate 100. The semiconductor bridge 400 may be disposed in a cavity C adjacent to an upper surface of the coreless circuit substrate 100. A first pad 470 of the semiconductor bridge 400 may be connected to lower surfaces of planar patterns for pads 150P, which are uppermost wiring layers opened by the cavity C, by a first conductive bump 490. The chip pads 350 of the first and second semiconductor chips 300A and 300B may be connected to the upper surfaces of the planar patterns for pads 150P by the second conductive bumps 390.

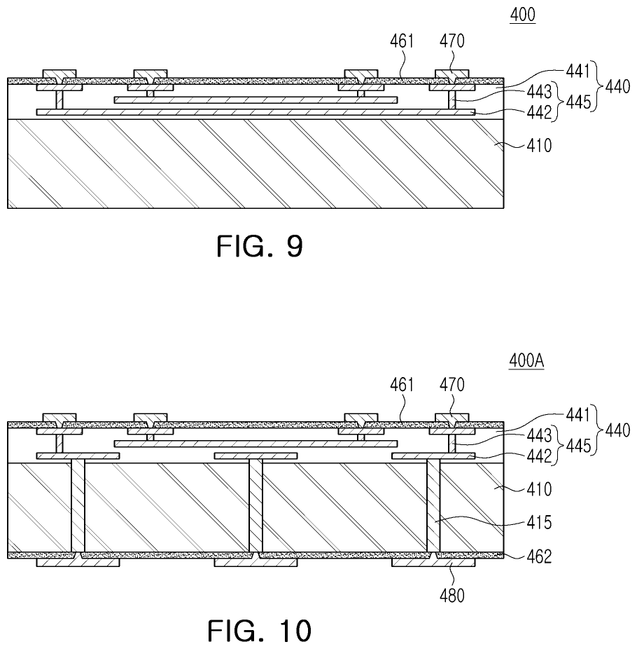

FIG. 9 is a cross-sectional side view illustrating a semiconductor bridge embedded in the circuit board of FIG. 7.

Referring to FIG. 9, the semiconductor bridge 400 may include a semiconductor body 410 and an interconnection structure 440 disposed on the upper surface of the semiconductor body 410. The interconnection structure 440 may include an insulating layer 441 and a redistribution layer 445 in the insulating layer 441. The redistribution layer 445 includes a redistribution pattern 442 and a redistribution via 443 connecting the redistribution pattern and may be configured to interconnect the first and second semiconductor chips 300A and 300B. Accordingly, the interconnection structure 440 may be provided as a signal path for interconnection of the first and second semiconductor chips 300A and 300B.

The semiconductor bridge 400 employed in the present embodiment may include first pads 470 aligned only on the cross-section, for example, the upper surface. The first pads 470 may be disposed on the first passivation film 461 and may be connected to the contact area of the redistribution layer 445. Similar to semiconductor-based chip capacitors 200A′, 200B′, 200C′ and 200D′, the semiconductor bridge 400 may include a semiconductor body 410 such as silicon having relatively high rigidity, and thus may be helpful in reinforcing the rigidity of the coreless circuit substrate 100 employed in the present embodiment.

In the present embodiment, the coreless circuit substrate 100 may include a plurality (for example, four) of cavities C1′, C2′, C3′ and C4′ at a level lower than the cavity C. The semiconductor-based chip capacitors 200A′, 200B′, 200C′ and 200D′ may be mounted at a level lower than the semiconductor bridge 400. The semiconductor-based chip capacitors 200A′, 200B′, 200C′ and 200D′ may be connected to the wiring layer 150 in a manner similar to the previous embodiments. First pads 270 of semiconductor-based chip capacitors 200A′, 200B′, 200C′ and 200D′ are connected to a wiring layer 150 exposed on the bottom of cavities C1′, C2′, C3′ and C4′ by first conductive bumps 290, and second pads 280 of semiconductor-based chip capacitors 200A′, 200B′, 200C′ and 200D′ are partially covered by an insulating layer 100h covering the cavities C1′, C2′, C3′ and C4′, and the wiring layer on the insulating layer 100h may be connected to the second pads 280 of the semiconductor-based chip capacitors 200A′, 200B′, 200C′ and 200D′ by an interconnection via 150V penetrating the insulating layer 100h. Respective at least some of the semiconductor-based chip capacitors 200A′, 200B′, 200C′ and 200D′ employed in the present embodiment may be arranged so as not to overlap the semiconductor bridge 400 in the thickness direction D3 of the coreless circuit substrate 100 to expand the area in which rigidity is reinforced.

The semiconductor bridge 400 introduced in the previous embodiment is exemplified as a single-sided pad structure, but may be implemented as a double-sided pad structure, similar to a semiconductor-based chip capacitor. FIG. 10 is a cross-sectional side view illustrating an example of a semiconductor bridge with a double-sided pad structure.

Referring to FIG. 10, the semiconductor bridge 400A according to the present embodiment may include, similar to the previous embodiment, a semiconductor body 410 and an interconnection structure 440 disposed on the upper surface of the semiconductor body 410. The interconnection structure 440 may include an insulating layer 441 and a redistribution layer 445 that interconnects the first and second semiconductor chips 300A and 300B.

First and second passivation films 461 and 462 are disposed on the upper surface of the interconnection structure 440 and the lower surface of the semiconductor body 410, respectively. The semiconductor bridge 400A employed in the present embodiment may include first pads 470 on the first passivation film 461 and second pads 480 on the second passivation film 462. In addition, the semiconductor bridge 400A may include a through-electrode 415 that is connected to the redistribution layer 445 and penetrates the semiconductor body 410. The first pads 470 may be connected to the redistribution pattern 442 of the interconnection structure 440 through the first passivation film 461, and the second pads 480 may be connected to the through-electrode 415 through the second passivation film 462.

In this way, the semiconductor bridge 400A employed in this embodiment has a double-sided pad structure having first pads 470 and second pads 480, and may be connected to the wiring layer 150 with a high degree of design freedom by utilizing the double-sided pad structure like a semiconductor-based chip capacitor.

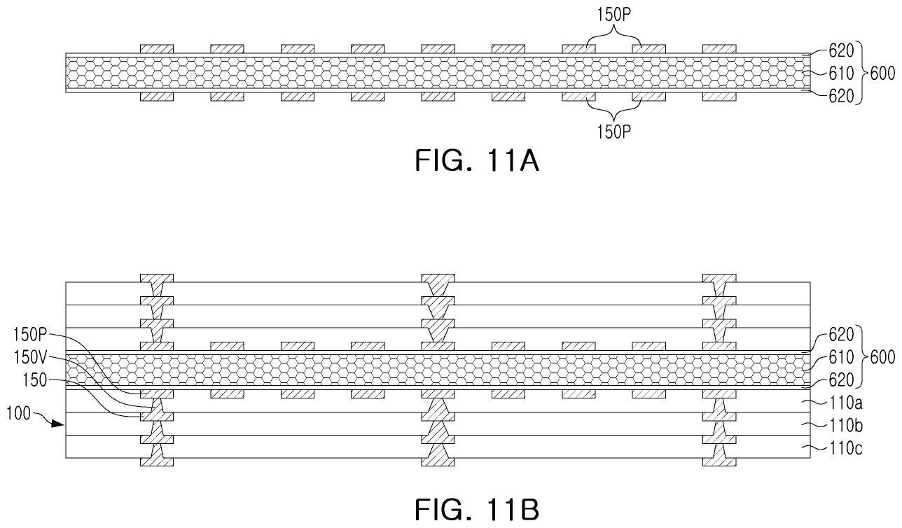

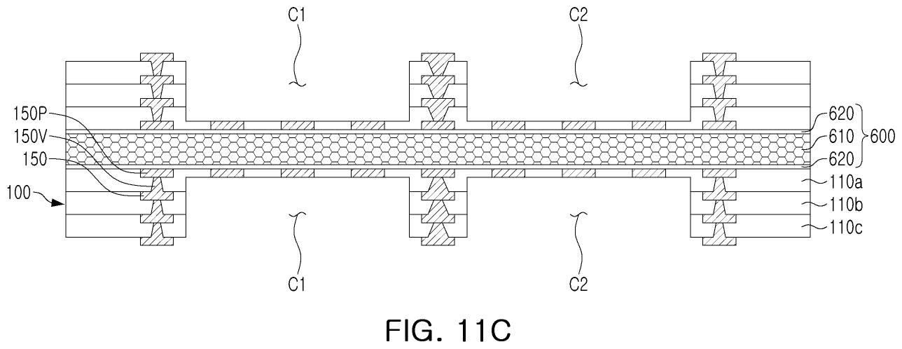

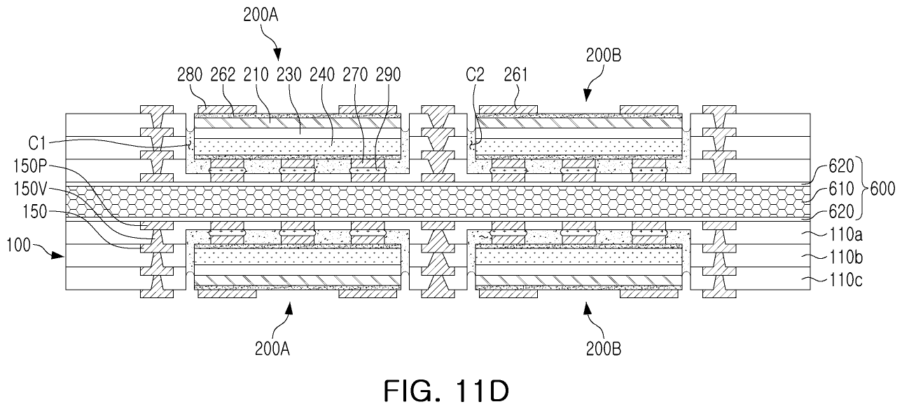

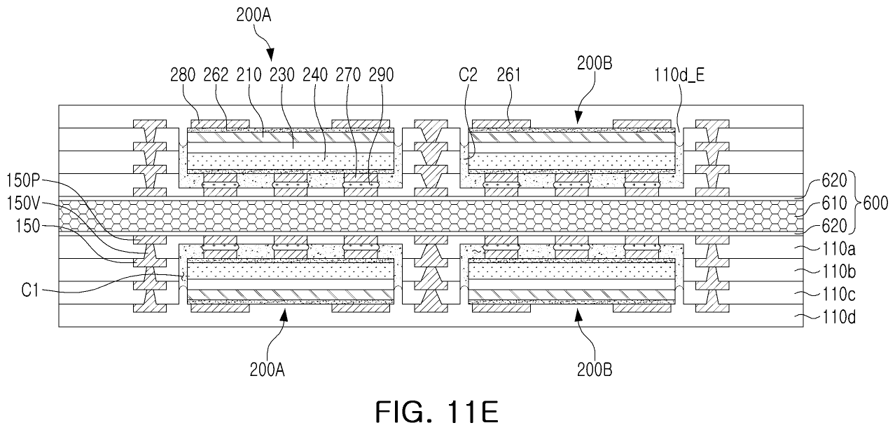

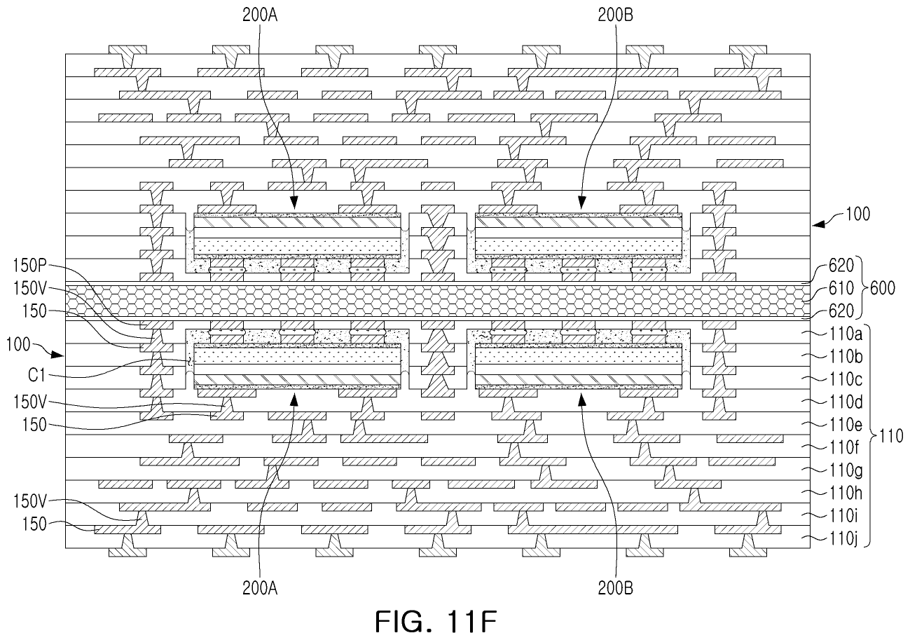

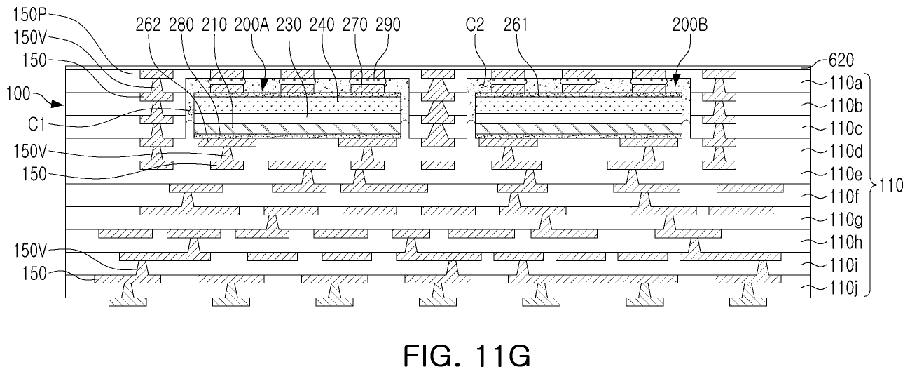

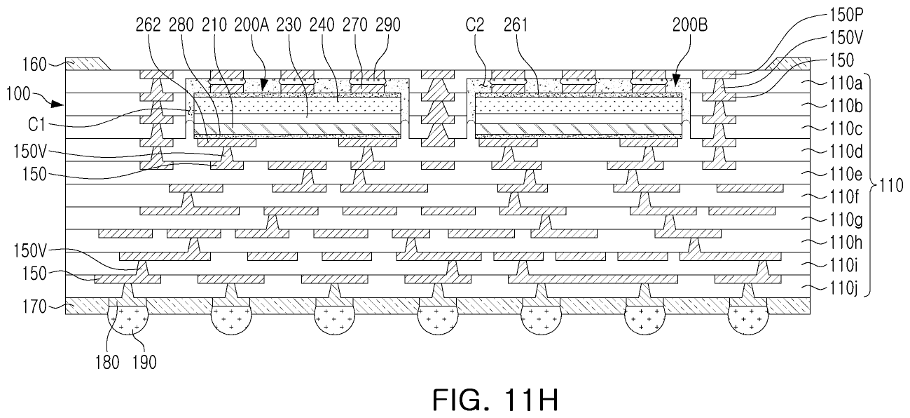

FIGS. 11A to 11G are cross-sectional views illustrating the main processes of a method of manufacturing a semiconductor package according to an example embodiment. The cross-sections of FIGS. 11A to 11G correspond to the cross-sections of the example embodiment of FIG. 1, and for convenience, the following description will focus on the configurations illustrated in each cross-section.

Referring to FIG. 11A, planar patterns for pads 150P may be formed as a wiring layer on both sides of a detach carrier film 600.

The detach carrier film 600 may include a carrier core 610 and a copper layer 620 respectively disposed on both sides of the carrier core 610. The copper layer may be used to form planar patterns for pads 150P by using a plating process. The planar patterns for pads 150P may be provided as the uppermost wiring layer of a circuit board and may be pads on which semiconductor chips are mounted. The planar patterns for pads 150P may have an arrangement corresponding to the arrangement of chip pads 350 of a semiconductor chip 300. In some embodiments, the arrangement of the planar patterns for pads 150P may correspond to the arrangement of the first pads 270 of the semiconductor-based chip capacitors 200A to 200D.

In this embodiment, the process of building up a multilayer circuit board simultaneously from both sides of a detach carrier film 600 is described, but is not limited thereto, and in some embodiments, the process of building up a multilayer circuit board from only one side of a detach carrier film may be performed.

Next, referring to FIG. 11B, after forming an insulating layer 110a covering a planar patterns for pads 150P, some wiring layers 150 and some insulating layers 110b and 110c may be formed.

After forming the insulating layer 110a to cover the planar patterns for pads 150P, layers of a certain thickness may be first built up to an area where a cavity is to be formed. The wiring layers 150 formed on the insulating layers 110b and 110c may be designed not to be located in an area where a cavity is to be formed. The wiring layer 150 may include an interconnection via 150V connected to another wiring layer 150 adjacent thereto. In this build-up process, after the insulating layers 110a, 110b and 110c are respectively formed, a via hole may be formed by using a mechanical drill or a laser drill using a CO₂ laser or YAG laser or by using a blast process, and then a conductive material may be applied to the inside thereof through a plating process or a paste printing process.

Next, referring to FIG. 11C, a plurality of cavities C1 and C2 may be formed in the insulating layers 110a, 110b and 100c.

The plurality of cavities C1 and C2 may be formed to have a depth d that is removed to a portion of the uppermost insulating layer 110a. In example embodiments, the depth d may correspond to a thickness of one to four insulating layers among the plurality of insulating layers 110. The planar patterns for pads 150P may be exposed through the plurality of cavities C1 and C2. For example, the cavities C1 and C2 may be formed using a mechanical drill or blast process, but are not limited thereto.

Next, referring to FIG. 11D, semiconductor-based chip capacitors 200A and 200B may be mounted in cavities C1 and C2, respectively.

The first pads 270 of the semiconductor-based chip capacitors 200A and 200B may be connected to the lower surfaces of the planar patterns for pads 150P by the first conductive bumps 290. In a subsequent process, the semiconductor chip (e.g., semiconductor chip 300 of FIG. 1) is connected to the upper surfaces of the planar patterns for pads 150P, so that the electrical path between the semiconductor-based chip capacitors 200A and 200B and the semiconductor chip (e.g., semiconductor chip 300 of FIG. 1) may be significantly shortened.

Next, referring to FIG. 11E, an insulating layer 110d covering semiconductor-based chip capacitors 200A and 200B within the cavities C1 and C2 may be formed.

In this process, before forming the insulating layer 110d, a filling material 120 may be applied to the remaining space of the cavities C1 and C2. For example, the filling material 120 may include an ABF material. Then, an insulating layer 110d may be formed to cover the semiconductor-based chip capacitors 200A and 200B within the cavities C1 and C2. In this process, a portion of the remaining space of the cavities C1 and C2 in which the chip capacitors 200A and 200B are disposed may be filled through the openings of the cavities C1 and C2.

Next, referring to FIG. 11F, a coreless circuit substrate 100 may be manufactured by forming other wiring layers 150 and other insulating layers 110e, 110f, 110g, 110h, 110i and 110j.

First, the wiring layer 150 on the insulating layer 110d may be formed to have interconnection vias connected to the second pads 280 of the semiconductor-based chip capacitors 200A and 200B.

Next, the remaining other wiring layers 150 and other insulating layers 110e, 110f, 110g, 110h, 110i and 110j may be secondarily built up on the insulating layer 110d. Similar to the process of FIG. 11B, the present build-up process may be performed by forming respective insulating layers 110e, 110f, 110g, 110h, 110i and 110j, forming a via hole by using a mechanical drill or a laser drill using a CO₂ laser or a YAG laser or by using a blast process, and then applying a conductive material to the inside through a plating process or a paste printing process.

Next, the coreless circuit substrates 100 may be separated from the detach carrier film 600. Referring to FIG. 11G, a separated coreless circuit substrate 100 is illustrated.

The copper layer 620 may remain on the upper surface of the separated coreless circuit substrate 100. This copper layer 620 may be removed through an additional etching process, and the required planar patterns for pads 150P may be opened as the uppermost wiring layer of the coreless circuit substrate 100. In some embodiments, a surface treatment layer for high-quality bonding may be formed on the planar patterns for pads 150P. The surface treatment layer may be provided by additionally plating a layer such as Au.

Next, referring to FIG. 11H, first and second passivation layers 160, 170 may be formed on the upper and lower surfaces of the coreless circuit substrates 100, respectively. In the first passivation layers 160, openings are formed to open the planar patterns for pads 150P to mount the semiconductor chip, and in the second passivation layers 170, multiple openings are formed to open contact areas of the lowermost redistribution layer 150L, and the UBM layer 180 and the external connection conductors 190 connected to the contact areas may be formed through the multiple openings, respectively. Finally, as illustrated in FIG. 1, the semiconductor package 500 according to the present embodiment may be manufactured by mounting the semiconductor chip.

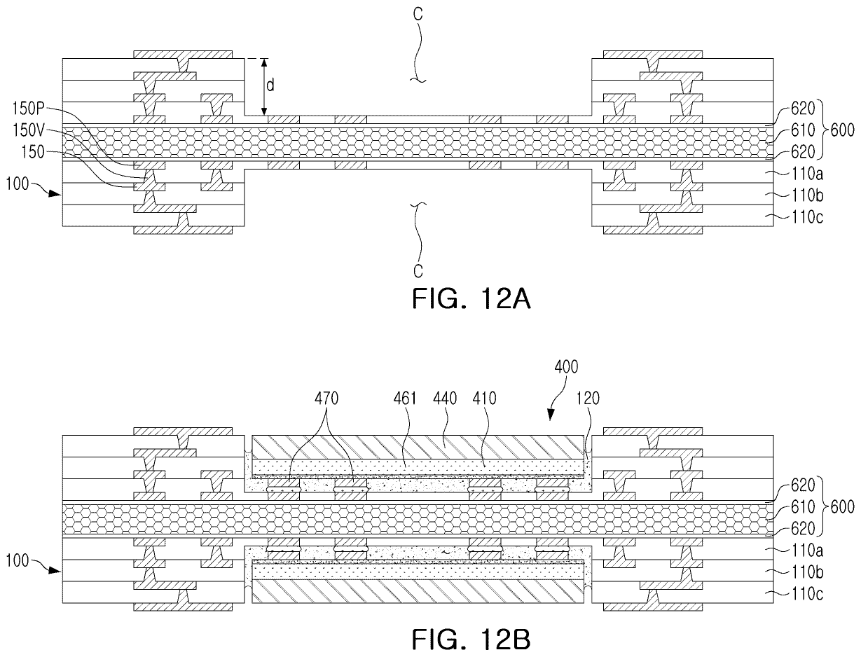

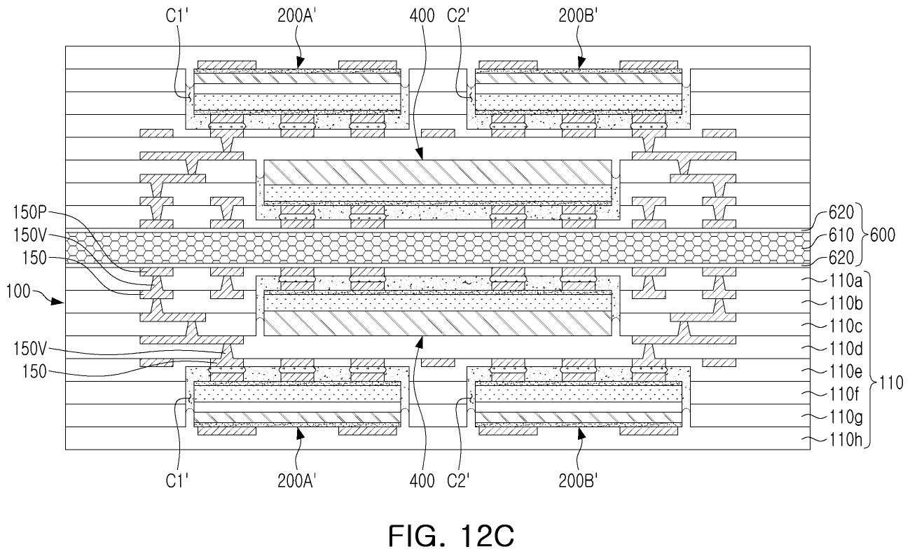

FIGS. 12A to 12C are cross-sectional views illustrating the main processes of the method of manufacturing the semiconductor package according to an example embodiment. FIGS. 12A to 12C may be understood as part of the process of the method of manufacturing the semiconductor package 500B illustrated in FIG. 7.

Referring to FIG. 12A, the cavity C may be formed to have a depth d that is removed to a portion of the uppermost insulating layer 110a. This process may be understood as a process performed after the processes of FIG. 11A and FIG. 11B of the previous embodiment are performed. The cavity C may be formed to have an area corresponding to the size of a semiconductor bridge to be mounted in a subsequent process. Planar patterns for pads 150P may be exposed through the cavity C. For example, the cavity C may be formed using a mechanical drill or blast process, but is not limited thereto.

Next, referring to FIG. 12B, a semiconductor bridge 400 may be mounted in the cavity C. The semiconductor bridge 400 may be disposed to be adjacent to the upper surface of the coreless circuit substrate 100. The first pads 470 of the semiconductor bridge 400 may be connected to the lower surfaces of the planar patterns for pads 150P which are the uppermost wiring layers opened by the cavity C by the first conductive bump 490.

Referring to FIG. 12C, after performing an additional build-up process, a plurality of additional cavities C1′ and C2′ may be formed, and semiconductor-based chip capacitors 200A′ and 200B′ may be mounted in respective cavities C1′ and C2′ (see FIG. 11D). Then, an insulating layer 110h covering the semiconductor-based chip capacitors 200A′ and 200B′ may be formed.

Additionally, the wiring layer 150 on the insulating layer 110h may be formed to have interconnection vias that are connected to the second pads 280 of the semiconductor-based chip capacitors 200A′ and 200B′. The remaining wiring layer 150 and the insulating layers 110i and 110j may be additionally built up on the insulating layer 110h (see FIG. 11F). Next, after separating from the detach carrier film 600, the copper layer 620 is removed, the first and second passivation layers 160, 170 are formed, and the UBM layer 180/external connection conductor 190 is formed, thereby manufacturing the semiconductor package 500B illustrated in FIG. 7.

As set forth above, according to the example embodiments described above, a plurality of semiconductor-based chip capacitors may be introduced into a relatively thin coreless circuit substrate, thereby reducing the size of the package and reinforcing the rigidity of the package. In an example embodiment, semiconductor-based chip capacitors may be embedded in an upper level, thereby shortening the path between the capacitor and the semiconductor chip, and thus securing power integrity characteristics.

While example embodiments have been illustrated and described above, it will be apparent to those skilled in the art that modifications and variations could be made without departing from the scope of the present inventive concept as defined by the appended claims.

What is claimed is:

1. A semiconductor package comprising:
a coreless circuit substrate including an insulating member having a plurality of insulating layers and a plurality of cavities, and a plurality of wiring layers respectively disposed on the plurality of insulating layers and having interconnection vias connected to adjacent wiring layers;
at least one semiconductor chip disposed on an upper surface of the coreless circuit substrate and electrically connected to an uppermost wiring layer among the plurality of wiring layers; and
a plurality of semiconductor-based chip capacitors disposed in the plurality of cavities, respectively, and each having an upper surface on which first pads are disposed and a lower surface on which second pads are disposed,
wherein the first pads are connected to a first wiring layer, adjacent to the first pads, among the plurality of wiring layers by conductive bumps, and the second pads are connected to an interconnection via of a second wiring layer, adjacent to the second pads, among the plurality of wiring layers.

2. The semiconductor package of claim 1, wherein the uppermost wiring layer includes planar patterns for pads corresponding to chip pads of the at least one semiconductor chip.

3. The semiconductor package of claim 2,
wherein the first wiring layer is provided as the uppermost wiring layer, and
wherein the first pads of the plurality of semiconductor-based chip capacitors are respectively connected to lower surfaces of the planar patterns for pads.

4. The semiconductor package of claim 1, wherein each of the plurality of semiconductor-based chip capacitors includes:
a semiconductor body having a first surface facing the upper surface of the coreless circuit substrate and a second surface positioned opposite the first surface,
a capacitor structure having a first electrode and a second electrode and a dielectric layer therebetween on the first surface of the semiconductor body,
a redistribution structure having a redistribution layer connected to the first electrode and the second electrode on the capacitor structure, and
a through-electrode penetrating the semiconductor body and connected to the second electrode.

5. The semiconductor package of claim 4,
wherein the capacitor structure includes a base insulating layer disposed on the first surface of the semiconductor body and having a plurality of trenches, and
wherein the first and second electrodes and the dielectric layer are provided along surfaces within the plurality of trenches.

6. The semiconductor package of claim 4,
wherein the first pads are electrically connected to the first electrode through the redistribution layer on the redistribution structure, and
wherein the second pads are electrically connected to the second electrode through the through-electrode on the second surface of the semiconductor body.

7. The semiconductor package of claim 1, wherein interconnection vias of the plurality of wiring layers have widths narrowing toward the upper surface of the coreless circuit substrate.

8. The semiconductor package of claim 1, wherein each of the plurality of cavities has a depth corresponding to a thickness of one to four insulating layers among the plurality of insulating layers.

9. The semiconductor package of claim 1,
wherein each of the plurality of cavities has an opening facing a lower surface of the coreless circuit substrate, and
wherein an insulating layer provided with the second wiring layer among the plurality of insulating layers fills at least a portion of the plurality of cavities.

10. The semiconductor package of claim 1, wherein the plurality of semiconductor-based chip capacitors includes first chip capacitors located at first levels of the coreless circuit substrate and second chip capacitors located at a second level lower than the first levels of the coreless circuit substrate.

11. The semiconductor package of claim 10, wherein at least some of the first chip capacitors are arranged so as not to overlap the second chip capacitors in a thickness direction of the coreless circuit substrate.

12. The semiconductor package of claim 1,
wherein the at least one semiconductor chip includes first and second semiconductor chips, and
wherein the semiconductor package further comprises a semiconductor bridge embedded in the coreless circuit substrate and having an interconnection wiring layer electrically connecting the first and second semiconductor chips.

13. The semiconductor package of claim 12, wherein at least a portion of each of the plurality of semiconductor-based chip capacitors is disposed so as not to overlap the semiconductor bridge in a thickness direction of the coreless circuit substrate.

14. A semiconductor package comprising:
a coreless circuit substrate including an insulating member having a plurality of insulating layers, and a plurality of wiring layers respectively disposed on the plurality of insulating layers, an uppermost wiring layer among the plurality of wiring layers including planar patterns for pads, and each of the plurality of wiring layers excepting the uppermost wiring layer having an interconnection via connected to another adjacent wiring layer;
a semiconductor chip disposed on an upper surface of the coreless circuit substrate and electrically connected to the planar patterns of the uppermost wiring layer; and
a plurality of semiconductor-based chip capacitors embedded in the coreless circuit substrate and each having an upper surface on which first pads are arranged and a lower surface on which second pads are arranged,
wherein the first pads are connected to lower surfaces of the planar patterns for pads of the uppermost wiring layer, and the second pads are connected to an interconnection via of a wiring layer adjacent thereto among the plurality of wiring layers.

15. The semiconductor package of claim 14, wherein interconnection vias of the plurality of wiring layers have a width narrowing toward an upper surface of the coreless circuit substrate.

16. The semiconductor package of claim 14, wherein the plurality of insulating layers include the same insulating material.

17. The semiconductor package of claim 14, wherein each of the plurality of semiconductor-based chip capacitors has a thickness in a range of 20 μm to 70 μm.

18. A semiconductor package comprising:
a coreless circuit substrate including an insulating member having a plurality of insulating layers, and a plurality of wiring layers respectively disposed on the plurality of insulating layers, an uppermost wiring layer of the plurality of wiring layers including planar patterns for pads, and each of the plurality of wiring layers excepting the uppermost wiring layer having an interconnection via connected to another adjacent wiring layer;
a plurality of semiconductor chips disposed on an upper surface of the coreless circuit substrate and electrically connected to the planar patterns of the uppermost wiring layer;
a semiconductor bridge embedded in the coreless circuit substrate and having an interconnection wiring layer electrically connecting the plurality of semiconductor chips; and
a plurality of semiconductor-based chip capacitors embedded in the coreless circuit substrate and having an upper surface on which first pads are arranged and a lower surface on which second pads are arranged,
wherein the first pads are connected to a first wiring layer adjacent to the first pads among the plurality of wiring layers by first conductive bumps, and the second pads are connected to an interconnection via of a second wiring layer adjacent to the second pads among the plurality of wiring layers.

19. The semiconductor package of claim 18,
wherein the semiconductor bridge includes connection pads on the interconnection wiring layer, and
wherein the connection pads are respectively connected to lower surfaces of the planar patterns for pads by second conductive bumps.

20. The semiconductor package of claim 18, wherein at least some of the plurality of semiconductor-based chip capacitors are arranged so as not to overlap the semiconductor bridge in a thickness direction of the coreless circuit substrate.
